(19) United States
(12) Patent Application Publication
(10) Pub. No.: US 2004/0016868 A1
(43) Pub. Date: Jan. 29, 2004

(54) Image processing apparatus

(76) Inventors: Patrick A. Cherry, Eagle, ID (US); Diana L. Cherry, Eagle, ID (US); J. Michael Dunlap, Horseshoe Bend, ID (US)

Correspondence Address: HEWLETT-PACKARD COMPANY, Intellectual Property Administration, P.O. Box 272400, Fort Collins, CO, 80527-2400, US

(21) Appl. No.: 10/201,682

(22) Filed: Jul. 23, 2002

(51) Int. Cl. H01L 27/00

(52) U.S. Cl. 250/208.1

(57) ABSTRACT

Apparatus are configured to perform optical scanning functions on scannable objects. In accordance with one embodiment of the present invention, an apparatus includes an imaging portion and a scanning portion, wherein the scanning portion is operatively located below the imaging portion. In accordance with another embodiment of the present invention, an apparatus includes an enclosure, a scan head operatively mounted within the enclosure, and a movable platen that is extensible relative to the enclosure to facilitate placement of scannable objects on the platen. In accordance with yet another embodiment of the present invention, an apparatus can include a sheet feeding mechanism that can be employed to automatically feed image-bearing sheets across the platen for scanning when the platen is retracted in the scan position.

### FIELD OF THE INVENTION

The invention claimed and disclosed herein pertains to image processing apparatus which incorporate optical scanners.

### BACKGROUND OF THE INVENTION

Optical scanners (“scanners”) are well known in the art. Scanners are capable of scanning, or “reading,” a visual image and then converting the visual image into an electronic format. Examples of visual images that can be scanned by a scanner for later conversion into an electronic format include documents containing text and/or graphics, as well as photographs. An example of an electronic format into which the scanned image can be converted is a digital file. Once the image is converted into an electronic format, the image can be electronically stored or transmitted, and in some instances the electronic format can be edited or modified.

The various processes by which scanners function are generally well known in the art. Typically, scanners include a scan head that is configured to move relative to the visual image to be scanned. That is, the image to be scanned can be moved past a stationary scan head, or the scan head can be moved past the image. The scan head generally includes both a light source and a light detection means. The light source is configured to direct light at the visual image to be scanned. Light reflected from the visual image is then detected by the light detection means. Typically, the light source is in the form of a cold cathode fluorescent lamp, a xenon lamp, or a standard fluorescent lamp.

The light detection means which is included in the scan head is generally in the form of an array of charge-coupled devices (“CCD's”). However, other forms of light detection means are known, such as the contact image sensor (“CIS”). In any case, the light detection means usually consists of a plurality of light sensitive photosites. Each photosite is generally configured to detect the relative intensity of light energy which is directed at the photosite. Furthermore, each photosite is configured to generate an electrical charge that is proportional to the intensity of the light detected.

In the operation of a typical scanner, light is generated by the light source and is directed towards the visual image to be scanned. The light is caused to reflect from the visual image, after which a discrete portion of the reflected light is detected by an associated photosite. Each photosite then generates an electrical charge which is representative of the relative intensity of the reflected light detected by the, photosite. In this manner, the array of photosites detects the image by detecting the relative locations of light and dark portions of the image. The electrical charges generated by the photosites are then typically converted to a standard electronic data format for storage and/or transmission of the image.

The scan head of a scanner also typically includes a variety of other components such as mirrors, lenses, filters and the like which are employed in directing light from the light source to the visual image and/or from the visual image to the light detection means. For example, various light filters and the like can be employed to detect color images, as is known in the art.

Additionally, a typical scanner includes a motive means that is employed to move the scan head relative to the visual image. In this manner, the scan head can be “swept” or moved relative to the visual image from one end thereof to the other in order to scan the entire visual image. Specifically, the motive means can be employed either to move the scan head past a stationary image, or to move the image past a stationary scan head.

Although several specific types of scanners are known, two of the most common types are those of the flatbed (or desktop) scanner and the sheet-fed scanner. The typical flatbed scanner includes a stationary, horizontal, glass plate, or platen, on which the visual image to be scanned is placed, usually in a face down position. The scan head is located beneath the platen and is configured to scan the visual image by sweeping, or moving, from one end of the platen to the opposite end. The scannable area of the typical flatbed scanner is at least equal to the size of a standard letter-sized sheet of paper. One advantage associated with a flatbed type of scanner is that virtually anything which can be placed on the platen can be scanned.

Sheet-fed scanners typically include a stationary scan head and a sheet feeding mechanism that moves a sheet of paper or the like past the scan head. As the sheet of paper is moved past the scan head, the visual images on the sheet are scanned by the scan head. One advantage associated with the sheet-fed type of scanner is that an entire stack of sheets can be scanned quickly and automatically by such a scanner.

Many flatbed scanners include a sheet feeding mechanism that enables such a flatbed scanner to function both in the manner of a flatbed scanner and a sheet-fed scanner. Such a sheet feeding mechanism is typically integrally incorporated into a platen cover that is supported on the scanner by way of hinges. In this manner, the cover can be pivoted by way of the hinges to expose the platen, wherein bulky objects such as books or the like can be placed on the platen for scanning. Alternatively, the cover can be placed in the closed position against the platen, wherein the integral sheet feeding mechanism can be employed to automatically feed a stack of sheets one-at-a-time onto, and off of, the platen for scanning.

Such a sheet feeding mechanism that is incorporated into a platen cover can employ any of a number of known means for moving sheets of media across the platen or the scan head for scanning. Typically, a sheet-picking device is employed in conjunction with an endless belt, although rollers or other such means can be employed. The picking device is configured to pick individual sheets of media from the input tray while the endless belt is configured to grip and move individual sheets of media to a scan position on the platen. Once the scanning process for the respective sheet is complete, the belt then moves the sheet from the scanning position to an outfeed tray.

In accordance with an alternative configuration that is also practiced in the art, the scan head is immobilized, or held in a fixed position relative to the platen whenever the sheet feeding mechanism is operated. That is, in such an alternative configuration, use of the sheet feeding mechanism dictates that the scan head is held in a fixed position relative to the platen while the sheet feeding mechanism causes the sheet of media to be swept past the scan head while the image is scanned. As in the case of the previously discussed configuration, an endless belt, or rollers, or other such means can be employed for sweeping the sheet past the scan head.

Optical scanners are oftentimes used in conjunction with imaging apparatus, as in the case of a photocopier which is employed to produce copies, or duplicates, of documents, photographs, and the like. Imaging apparatus are generally employed for converting the electronic data into a visual image. That is, imaging apparatus are generally configured to convert electronic data that is representative of a visual image into an actual visual image. A common type of imaging apparatus is known as a “printer.” Various specific types of printers are known, and two of the more common types of printers are those known as laser printers and inkjet printers.

When a printer is used in combination with a visual scanner, the resulting combination can be extremely versatile. For example, the combination can be employed for printing images directly from a computer hard drive, for example. The combination can also be utilized for producing copies of images by first scanning the original image and then printing a duplicate of the image. Moreover, such a combination of printer and scanner can be used for scanning images directly into a computer hard drive or onto another electronic data storage media such as a compact disk or diskette. Once the image is electronically stored, it can be later printed, transmitted, or altered.

Consequently, a recent trend in the design and marketing of computer peripheral devices is that of the “all-in-one” printer/scanner. Such “all-in-one” devices include both a printer and a flatbed scanner, which in combination can function as a printer, a photocopier, a scanner, and/or a facsimile machine. Such all-in-one devices also typically include a sheet feeding mechanism that functions in either of the manners described above.

Generally, the platen of such all-in-one devices is located at the top of the device in order to provide convenient access to the platen for scanning. Although a separate standalone printer and a stand-alone scanner can be operatively connected to one another in order to function in the manner of an all-in-one device, such a combination usually requires twice the desktop space compared to an all-in-one device. This is due to the fact that printers and scanners generally cannot be stacked upon one another.

However, even in cases wherein a printer and scanner can be stacked upon one another, the scanner generally must be stacked on top of the printer in order to provide acceptable access to the platen. That is, with regard to either an all-in-one device or a stacked printer/scanner combination, access to the platen would be available only in cases wherein the platen is located on top.

Although such prior art apparatus are known to function satisfactorily, at least one disadvantage can be associated with such prior art configurations. Specifically, due to the height of the platen on some prior art all-in-one apparatus, the platen is difficult to access for wheelchair-bound users. Furthermore, the platen on such prior art all-in-one apparatus can be difficult to access for anyone sitting in a chair. That is, when prior art apparatus are supported on a tabletop or desk top, the platen is generally too high to be fully visible to users who are not standing. As a result, proper placement and alignment of scannable documents and the like upon the platen is often impeded unless the user is able to stand while using the apparatus.

What is needed then is an image processing apparatus which achieves the benefits to be derived from similar prior art devices, but which avoids the shortcomings and detriments individually associated therewith.

### SUMMARY OF THE INVENTION

The image-processing apparatus in accordance with the various embodiments thereof which are described herein generally includes a scan head operatively housed within an outer enclosure. A platen is also included in the apparatus, wherein the platen is supported so as to be extensible relative to the enclosure. That is, the platen can be moved relative to the enclosure between a retracted scan position and an extended load position. When in the scan position, the platen is located within the enclosure and in operative orientation relative to the scan head wherein scannable objects that are supported on the platen can be scanned by the scan head. Conversely, when in the load position, the platen is extended substantially outside of the enclosure to facilitate placement of scannable objects onto the platen. Movement of the platen between the scan position and the load position does not effect the position of the scan head.

These and other aspects and embodiments of the present invention will now be described in detail with reference to the accompanying drawings, wherein:

### DESCRIPTION OF THE DRAWINGS

FIG. 1 is an isometric view in which the apparatus in accordance with one embodiment of the present invention is depicted.

FIG. 2 is a top view in which the apparatus in accordance with another embodiment of the present invention is depicted.

FIG. 3 is another top view of the apparatus depicted in FIG. 2, wherein the platen is shown in the extended position.

FIG. 4 is a side view of the apparatus depicted in FIG. 2.

FIG. 5 is another side view of the apparatus depicted in FIG. 2, wherein the platen is shown in the extended position.

FIG. 6 is a front view of the apparatus depicted in FIG. 2.

FIG. 7 is another front view of the apparatus depicted in FIG. 2 in which an alternative configuration consisting of additional components is shown.

FIG. 8 is a side view of the apparatus depicted in FIG. 7, wherein the sheet feeding mechanism is shown in a raised position.

FIG. 9 is an isometric view of the apparatus in accordance with yet another embodiment of the present invention, wherein the relative elevations of various components are shown.

### DETAILED DESCRIPTION OF THE INVENTION

In accordance with one embodiment of the present invention, an image processing apparatus includes an imaging portion and a scanning portion, wherein the scanning portion is operatively located below the imaging portion. The functionality of the scanning portion can be enhanced and/or facilitated by way of an extensible platen operatively supported by the scanning portion, wherein the platen is located substantially below the imaging portion. The platen is preferably movable between an operative scan position for scanning of scannable objects supported on the platen, and a load position in which the platen is substantially extended to facilitate placement of scannable objects thereon.

In accordance with another embodiment of the present invention, an image processing apparatus includes an enclosure and a scan head that is operatively mounted within the enclosure. An extensible platen is also included in the apparatus, wherein the platen is movable relative to the enclosure between a scan position and a load position. When in the scan position, the platen is substantially retracted within the enclosure and operatively oriented relative to the scan head, and when in the load position, the platen is substantially extended outside of the enclosure. The apparatus can include a sheet feeding mechanism operatively located within the enclosure, whereby sheets of image-bearing media can be automatically moved across the platen for scanning by the scan head when the platen is in the scan position.

In accordance with yet another embodiment of the present invention, an image processing apparatus includes a chassis, an enclosure supported on the chassis, a scan head operatively supported on the chassis, and a substantially flat and rigid platen that is movably supported on the chassis. T he platen can be selectively moved relative to the chassis between a retracted scan position and an extended load position. The platen is operatively located above the scan head and substantially within the enclosure when the platen is in the scan position. When the platen is in the load position, the platen is located substantially outside of the enclosure to facilitate placement of scannable objects thereon for scanning.

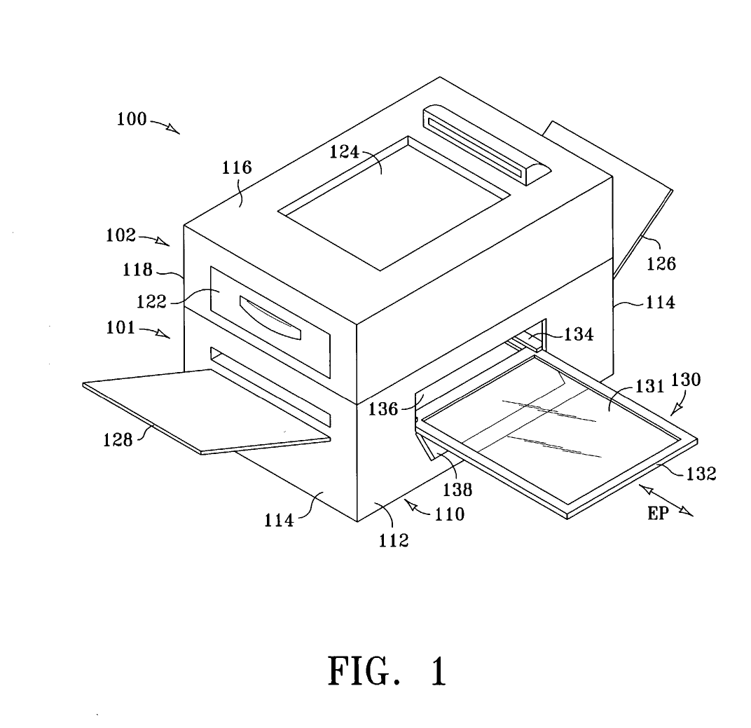

With reference to FIG. 1, an isometric view is shown in which an image processing apparatus 100 in accordance with one embodiment of the present invention is depicted. The apparatus 100 preferably includes both a scanning portion 101 and an imaging portion 102. However, as will become apparent with respect to the description of additional embodiments of the present invention as discussed below, the inclusion of the imaging portion 102 of the apparatus 100 is optional. That is, an apparatus in accordance with any of the various embodiments of the present invention can be provided with or without an imaging portion or an imaging device, as will become more apparent in later discussion.

The scanning portion 101 is configured to perform optical scanning functions generally in the manner described above with respect to the prior art. That is, the scanning portion 101 is configured to optically scan visual images for conversion thereof into an electronic format. Similarly, the imaging portion 102 is configured to produce images on imaging media (not shown) generally in the manner described above with respect to the prior art. Thus, it is understood that an apparatus in accordance with the present invention can be referred to as an “image processing” apparatus.

As is seen, the scanning portion 101 is operatively located below the imaging portion 102. That is, when the apparatus 100 is set up for operation, the scanning portion 101 is generally located below the imaging portion 102. The scanning portion 101 and the imaging portion 102 can each be discrete modular units which are operatively connectable with one another, wherein the imaging portion is operatively supportable on and above the scanning portion, and wherein the imaging portion and scanning portion are communicably linked for data transmission there between by way of any of a number of known means.

That is, the scanning portion 101 and the imaging portion 102 can each be discrete units that are separable from one another, and which are also operatively connectable with one another wherein the imaging portion is stackable upon the scanning portion. Alternatively, the scanning portion 101 and the imaging portion 102 can be integrally combined into a single unitary apparatus, such as an all-in-one unit, wherein the scanning portion is operatively located below the imaging portion.

Still referring to FIG. 1, the apparatus 100 preferably includes an enclosure 110. Enclosures are well known and widely employed in the art. The enclosure 110 is employed protect the various delicate internal components of the apparatus 100 from inadvertent damage. The enclosure also serves to prevent the intrusion of debris, such as dust and the like, into the internal workings of the apparatus 100. Moreover, the enclosure 110 tends to prevent exposure of users to danger posed by mechanical and electrical power and the like.

The enclosure 110 can be fabricated from a suitable material such as injection-molded plastic. If the apparatus 100 is configured as described above wherein the scanning portion 101 and the imaging portion 102 are discrete units, then the enclosure 110 is similarly divided into two discrete portions wherein one portion is exclusively associated with the imaging portion and the other portion is exclusively associated with the scanning portion. Conversely, if the apparatus 100 is configured so that both the scanning portion 101 and the imaging portion 102 are integrally incorporated into a single unit, then the enclosure 110 is preferably configured as a continuous unit.

The enclosure 110 is preferably configured in the general shape of a rectangular cube as depicted, although other shapes are possible. Specifically, the enclosure 110 preferably defines a front wall 112, along with two opposite, substantially parallel, spaced-apart and juxtaposed side walls 114 as shown. The side walls 114 are preferably substantially perpendicular to the front wall 112. The enclosure 110 also preferably defines a top wall 116 which is preferably substantially horizontal and also preferably substantially perpendicularly oriented relative to the front wall 112 and to each of the side walls 114. A back wall 118 is also preferably defined by the enclosure 110, wherein the back wall is preferably parallel, and spaced-apart in juxtaposed relation, to the front wall 112. A bottom wall (not shown) is also preferably included to complete the enclosure 110.

The apparatus 100 preferably includes a chassis or frame (not shown) on which the enclosure 110, as well as other various components, are supported. As is described above with respect to the enclosure 110, the chassis is divided into two discrete units in the case wherein the scanning portion 101 and the imaging portion 102 are each discrete units. Similarly, if the scanning portion 101 and the imaging portion 102 are integrally combined into a unitary apparatus, then the chassis can likewise be fabricated as a unitary frame for supporting both portions.

The imaging portion 102 preferably includes at least one fresh media tray 122 that is preferably internal to the imaging portion and is configured in the manner of a drawer or the like that is accessed through one of the side walls 114 of the enclosure 110. Clean imaging media (not shown) is stored in the fresh media tray 122 for use by the imaging portion 102 in producing images. The configuration and function of such fresh media trays is well known and widely employed in the art.

The imaging portion 102 also preferably includes an output tray 124. The output tray 124 is employed to receive image-bearing media sheets (not shown) which have been produced by the imaging portion 102. The general concept of output trays is well known and widely employed in the art as are the configuration and functionality of output trays. The output tray 124 can be defined in top wall 116 of the enclosure 110 as shown. Thus, when the imaging portion 102 produces an image on a media, such as a sheet of paper, the media sheet is drawn from the fresh media tray 122, whereupon an image is produced on the media sheet. Thereafter, the image-bearing media sheet is deposited into the output tray 124 to await retrieval by the user of the apparatus 100.

With continued reference to FIG. 1, the apparatus 100 includes a movable platen 130. The platen 130 is “movable” in the sense that the platen can be selectively moved relative to the enclosure 110. The platen 130 is preferably substantially flat and substantially rigid. Also, the platen 130 is preferably located below the imaging portion 102. The platen 130 functions as a surface on which a scannable object (not shown) is supported during the scanning process. The term “scannable object” as used herein is defined as an image-bearing object which the apparatus 100 is configured to scan.

Such scannable objects can include, for example, documents, photographs, books, and the like. Thus, the movable nature of the platen 130 serves to facilitate placement of a scannable object thereon for scanning as will be discussed in greater detail below. It is understood that the general concept of placing and supporting a scannable object upon a platen for scanning is so well known that the depiction of a scannable object in the accompanying figures will not serve to further the understanding of the present invention. Thus, scannable objects have been omitted from the accompanying figures in the interest of promoting clear illustrations of the actual invention in accordance with it's various embodiments.

The platen 130 preferably includes a transparent plate 131 such as a pane of glass or the like. The plate 131 is preferably surrounded by a peripheral supporting frame 132 which serves to support the plate and to protect the edge of the plate. The platen 130 is preferably extensible between a scan position and a load position to thereby facilitate the placement of a scannable object onto the platen for scanning. That is, the platen 130 is preferably configured to be extended from a scan position, wherein the platen is located wholly within the enclosure 110, to a load position wherein the platen protrudes substantially outside the enclosure. More preferably, the platen 130 is slidably movable between the scan position and the load position.

As depicted in FIG. 1, the platen 130 is located in the load position, wherein the platen has been extended and is protruding substantially outside of the enclosure 110. Such positioning of the platen 130 in the load position allows access to the platen for placement of a scannable object thereon, as is seen. Preferably, the movable platen 130 is extensible along an extension path EP. The extension path EP is preferably straight, and is more preferably also substantially horizontal.

Most preferably, the movable platen 130 is substantially horizontally oriented when in either the scan position or the load position. The apparatus 100 preferably includes a guide device 134 that is configured to movably support the platen 130 and to thereby facilitate movement thereof a long the extension path EP. The guide device 134 can be configured in any of a number of various manners as will be discussed in greater detail below. The apparatus 100 can include a pair of guide devices 134, wherein one guide device is associated with each opposite side of the platen 130.

In operation of the apparatus 100, a scannable object can be placed, or loaded, upon the platen 130 while the platen is extended in the load position. Once the scannable object is loaded onto the platen 130, the platen can be moved from the load position to the scan position. That is, when the platen is moved from the load position to the scan position after a scannable object has been loaded thereon, the scannable object moves with the platen to the scan position wherein both the platen and the scannable object are preferably wholly located within enclosure 110. When platen 130 has been moved into the scan position with the scannable object supported thereon, the scanning process can commence, as will be described in greater detail below.

Further reference to FIG. 1 reveals that the enclosure 110 defines an opening 136 therein. Preferably the opening 136 is defined in the front wall 112 of the enclosure 110 as depicted. As is also seen, the platen 130 is preferably configured to move through the opening 136 when moving between the scan position and the load position. That is, preferably, movement of the platen 130 along the extension path EP results in movement of the platen through the opening 136.

The apparatus 100 preferably includes a panel 138. The panel 138 is configured to substantially close the opening 136 when the platen 130 is in the load position and within the enclosure 110. That is, the panel 138 is configured to be movable between an open position and a closed position relative to the opening, wherein the opening 136 is either open or closed, respectively. The panel 138 can be operatively supported with respect to the apparatus in any of a number of possible manners. For example, as depicted in FIG. 1, the panel 138 can be pivotally connected to the enclosure 110, whereby the panel can be pivoted between an open position as shown and a closed position, wherein the opening 136 is substantially closed and sealed.

The platen 130 can be configured to be manually movable between the scan position and the load position. That is, the platen 130 can be configured so as to be manipulated by a user of the apparatus 100, whereby such manipulation results in movement of the platen between the scan position and the load position. For example, the platen 130 can be configured to be grasped by a user of the apparatus 100 and manually moved between the scan position and the load position. Similarly, the panel 138 can be configured to be manually moved between the open and closed positions.

Alternatively, movement of the platen 130 between the scan position and the load position can be either partially or fully assisted by way of an actuator member (not shown) such as a spring, or an automatic motive device. For example, such an actuator member can be in the form of a spring that is operatively connected to the platen 130, wherein the spring is compressed when the platen is moved from the load position to the scan position. When a user desires to move the platen from the scan position to the load position, the spring can be released by way of a trigger mechanism (not shown) or the like, whereby the platen is at least partially moved under the force of the spring toward the load position.

Similarly, the actuator member can be in the form of a motive device (not shown) such as an electric motor or solenoid or the like that is operatively connected to the platen 130. A control switch (not shown) or the like can be connected to such a motive device, whereby manipulation of the control switch by a user causes the motive device to automatically move the platen 130 between the scan position and the load position. The movement of the platen 130 byway of an actuator member will be discussed in greater detail below.

Still further reference to FIG. 1 reveals that the apparatus 100 can be configured for automatic sheet feeding of image-bearing media for scanning by the scanning portion 101. That is, the scanning portion 101 can include a sheet feeding mechanism (not shown), as well as a sheet feed input tray 126 and a sheet feed output tray 128. Sheet feeding mechanisms are known in the art and have been discussed above with respect to the prior art.

During operation of the apparatus 100, the platen 130 is preferably placed in the scan position after removing all scannable objects therefrom. One or more image-bearing media sheets (not shown) can be placed on the sheet feed input tray 126, whereupon the sheet feeding mechanism is activated so as to commence operation. The sheet feeding mechanism then picks sheets of image-bearing media one-at-a-time from the sheet feed input tray 126 and moves the sheets over the platen 130 for scanning. After being scanned in this manner, the sheets are moved by the sheet feeding mechanism to the sheet feed output tray 128. Such as sheet feeding mechanism will be discussed in greater detail below.

Turning now to FIG. 2, a top plan view is shown in which an image-processing apparatus 200 in accordance with another embodiment of the invention is depicted. As is seen, the apparatus 200 includes an enclosure 110 which is described above with respect to the apparatus 100 (shown in FIG. 1). Preferably, the enclosure 110 of the apparatus 200 has side walls 114, a top wall 116, a back wall 118, and a front wall 112, all of which are also described above with respect to the apparatus 100.

Moreover, the apparatus 200 also preferably includes a movable platen 130 that is depicted in FIG. 2 as being in the retracted scan position, wherein the platen is substantially within the enclosure. A guide device 134 is also preferably included in the apparatus 200. Both the movable platen 130 and the guide device are described above with respect to the apparatus 100. The apparatus 200 can also include a handle 231 that is connected to the platen 130 to facilitate manual movement of the platen between the scan position and the load position.

The apparatus 200 also includes a scan head 240 that is operatively mounted within the enclosure 110. Scan heads are known and have been discussed above with respect to the prior art. The scan head 240 is operatively movable along a scan path SP. That is when a scannable object (not shown) is placed on the platen 130 for scanning, and when the platen and the scannable object are placed in the scan position, the scan head 240 moves along the scan path SP during scanning of the scannable object.

As a further study of FIG. 2 reveals, the apparatus 200 can include a selectively activatable actuator member 260 that is operatively connected to the platen 130. As briefly described above, the actuator member 260 is preferably configured so that selective activation thereof causes the platen 130 to move between the scan position and the load position. The actuator member 260 can be configured in any of a number of manners as also described briefly above.

For example, the actuator member 260 can be a resilient member such as a spring that is compressible so as to store mechanical energy therein by way of manual movement of the platen 130 from the extended load position to the retracted scan position. The mechanical energy thus stored in such a spring can be selectively released by a user so as to at least partially move the platen from the retracted scan position to the extended load position.

Alternatively, the actuator member 260 can be a selectively activatable motive device such as an electric motor or the like that is operatively connected to the platen 130 so as to automatically move the platen between the scan position and the load position as selected by a user of the apparatus 200. It is understood that the operation and control of automatic motive devices are known in the art and thus need not be explained in further detail herein. It is further understood that various control means typically employed for operation of such automatic motive devices are known and are not depicted in the accompanying figures in the interested of clarity.

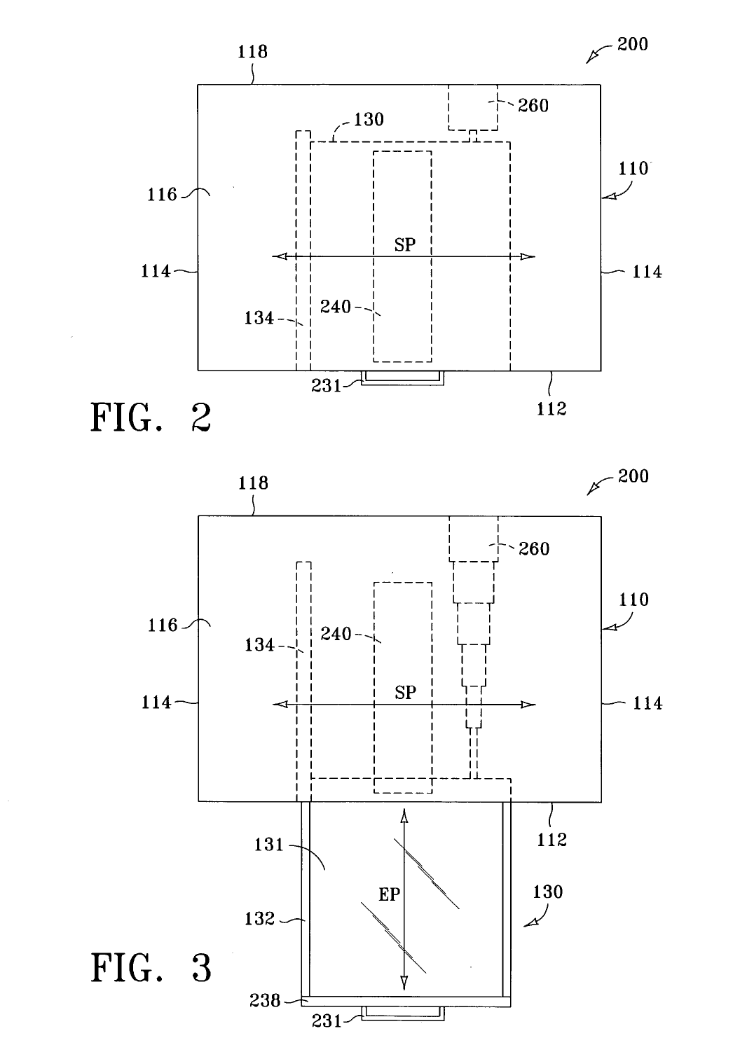

Moving now to FIG. 3, another top plan view is shown in which the apparatus 200 is depicted. However, as depicted in FIG. 3, the platen 130 of the apparatus 200 is shown to be located in the load position. That is, as shown in FIG. 3, the platen has been extended so as to protrude outside of the enclosure 110. As is seen, substantially all of the platen 130 is visible in FIG. 3 as compared to being hidden by the enclosure 110 as shown in FIG. 2. As has been already described above, the platen 130 can include a transparent plate 131 as well as a support frame 132. Additionally, a panel 238 can be mounted on the platen 130 as will be explained in greater detail below.

Still referring to FIG. 3, it is seen that the platen 130 can be extended and retracted relative to the enclosure 110. That is, the platen 130 is extensible from a scan position within the enclosure 110 to a load position substantially outside of the enclosure. Likewise, the platen is retractable from the load position substantially outside the enclosure 110 to a scan position within the enclosure. Furthermore, it is seen that the platen 130 is movable along the extension path EP between the scan position and the load position. Moreover, the apparatus 200 can be configured so that the extension path EP is substantially perpendicular to the scan path SP.

It is noted that movement of the platen 130 along the extension path EP does not necessarily affect the position of the scan head 240. That is, with the scan head 240 operatively mounted within the enclosure 110, the platen 130 can be extensible relative to the scan head, wherein the platen is extensible from the scan position to the load position without affecting the position of the scan head relative to the enclosure. In other words, the platen 130 is preferably movable along the extension path EP without affecting the position of the scan head 240 relative to the enclosure 110.

Moving to FIG. 4, a side view is shown in which the apparatus 200 is depicted. As is seen, the apparatus 200 can be supported on a support surface SS such as a table top, a desk top, or the like. As is also indicated by the absence of an imaging portion (such as the imaging portion discussed above and shown in FIG. 1), it is understood that the apparatus 200 need not include an imaging portion. That is, the apparatus 200 can be configured as a scanner without an imaging portion, as depicted. However, it is understood that the apparatus 200 can be configured to include an imaging portion in the manner described above and shown in FIG. 1 with respect to the apparatus 100.

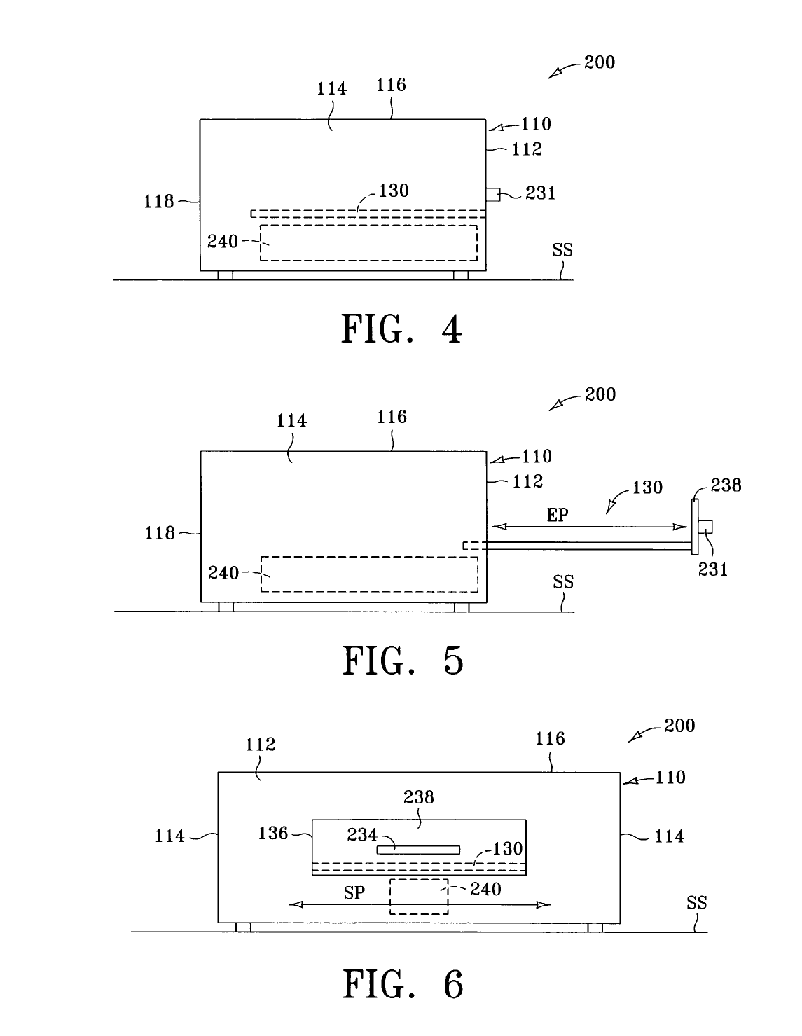

Still referring to FIG. 4, the platen 130 is shown in the scan position, wherein the platen is retracted within the enclosure 110. Furthermore, it is seen that the platen 130, when in the scan position, is preferably located above the scan head 240 and in juxtaposed operative relation thereto. That is, when the platen 130 is located in the scan position within the enclosure 110, the scan head 240 is located in juxtaposed orientation relative to the platen, whereby the scan head is operative so as to scan a scannable object that can be supported on the platen and within the enclosure. It is noted that the actuator member 260 as well as the guide device 134 have been omitted for clarity in FIG. 4, and also in FIGS. 5 and 6 which are discussed below.

Now moving to FIG. 5, another side view is shown in which the apparatus 200 is depicted. However, in contrast with the depiction of the apparatus in FIG. 4, the apparatus is depicted in FIG. 5 with the platen 130 in the load position, wherein the platen is extended so as to be substantially outside of the enclosure 110. That is, it is seen that the platen 130 has been moved, or extended, along the extension path EP to the load position so as to substantially protrude from the enclosure 110. It is further seen that the scan head 240 is preferably configured so as to remain within the enclosure 110 when the platen 130 is moved to the load position. That is, as explained above, it is seen from an examination of FIGS. 4 and 5 that the position of the scan head is preferably not effected by movement of the platen 130 along the extension path EP.

The depiction of, the apparatus 200 in FIG. 5 also provides a better understanding of the configuration of the panel 238 that is preferably rigidly mounted on the platen 130. That is, in accordance with one embodiment of the present invention, the panel 238 is rigidly fixed to one end of the platen 130 such that when the platen is retracted in the scan position within the enclosure 110, the panel substantially closes the opening (not shown) defined in the enclosure through which the platen passes when moving along the extension path EP as discussed above. Conversely, when the platen 130 is extended to the load position substantially outside of the enclosure 110, the panel 238 is spaced apart from the enclosure as shown.

Moving now to FIG. 6, a front view is shown in which the apparatus 200 is depicted. The opening 136 defined in the front wall 112 of the enclosure 110 is visible as revealed by an examination of FIG. 6. As discussed above, the platen 130 is preferably configured to pass through the opening 136 when the platen moves between the scan position and the load position. As is also seen, the panel 238 is preferably configured with a close-tolerance fit within the opening 136 so as to substantially seal the opening when the platen 130 is located in the scan position within the enclosure 110. Moreover, the scan head 240 is seen to be operatively located within the enclosure 110 and preferably below the platen 130 so as to be operatively movable along the scan path SP.

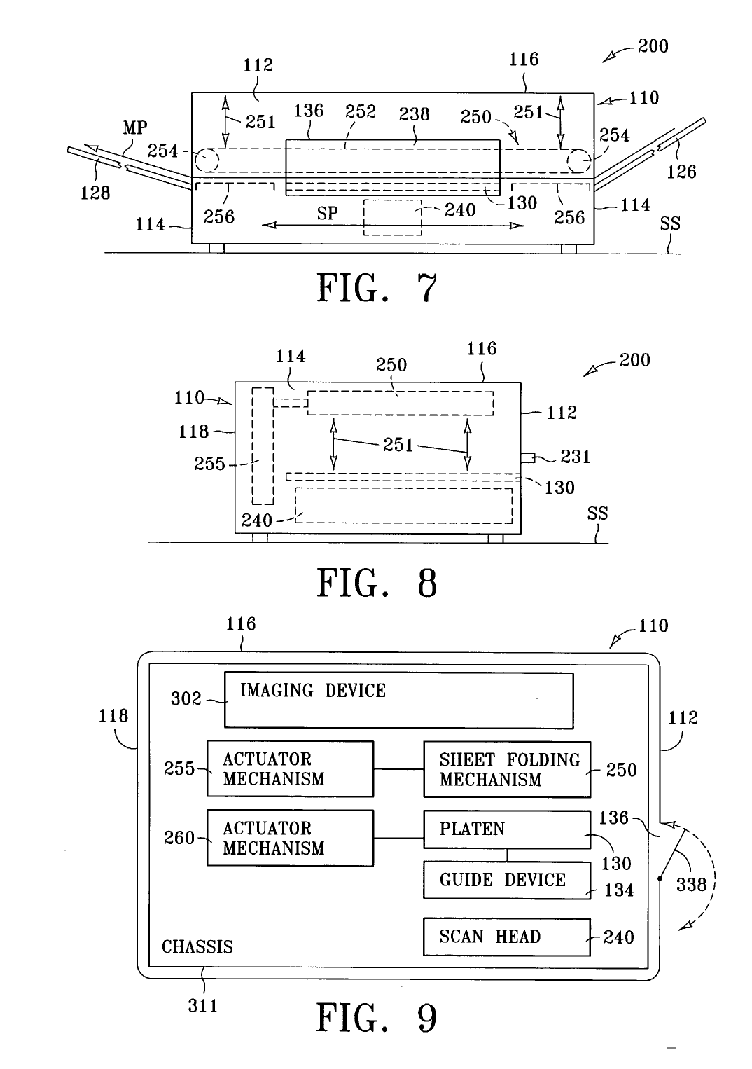

Now moving to FIG. 7, another front view is shown in which the apparatus 200 is depicted, except that several optional components are depicted in an alternative configuration of the apparatus. That is, as depicted in FIG. 7, the apparatus 200 includes several optional components that include a feed input tray 126, a feed output tray 128, and a sheet feeding mechanism 250, all of which have been briefly discussed above. The feed input tray, the feed output tray 128, and the sheet feeding mechanism 250 are configured to automatically feed sheets of image-bearing media (not shown), such as paper sheets and the like, through the apparatus 200 for scanning by the scan head 240.

More specifically, the apparatus 200 can include a sheet feeding mechanism 250 that is operatively located within the enclosure 110, as shown. Preferably, a sheet path MP is at least partially defined by the sheet feeding mechanism 250, wherein sheets of image-bearing media are movable along the sheet path to thereby pass through the enclosure 110 and across the platen 130 when the platen is in the scan position. Preferably, the sheet path MP is substantially parallel to the scan path SP as shown.

It is understood that the sheet feeding mechanism 250 can be configured in any of a number of possible manners. For example, the sheet feeding mechanism 250 can comprise a set of rollers 254 that are operatively supported within the enclosure 110. The rollers 254 are preferably configured to operatively support thereon an endless belt 252 that is, in turn, configured to move sheets of image-bearing media along the sheet path MP.

Various guides 256 can also be included in the sheet feeding mechanism 250 to facilitate movement of image-bearing media along the sheet path MP. However, it is understood that other specific configurations of the sheet feeding mechanism 250 are possible, but which are not shown or described herein. For example, an alternative configuration of the sheet feeding mechanism 250 can include rollers but no endless belt, wherein such rollers directly contact and move sheets of image-bearing media along the sheet path MP.

It is further understood that the sheet feeding mechanism 250 can be configured to operate in conjunction with the scan head in any of a number possible operational schemes. For example, in accordance with one operational scheme, the sheet feeding mechanism 250 can be configured to move sheets of image-bearing media across the platen 130 for scanning by the scan head 240 while the scan head is held in a fixed position relative to the enclosure 110.

In accordance with an alternative operational scheme, the sheet feeding mechanism 250 can be configured to move sheets of image-bearing media into position on the platen 130, wherein each sheet is held by the sheet feeding mechanism in a fixed position relative to the enclosure 110 while the scan head moves along the scan path SP for scanning. In any case, the sheet feeding mechanism 250 is preferably configured to move sheets of image-bearing media one-at-a-time from the feed input tray 126 and into the feed output tray 128, wherein therebetween each sheet is scanned by the scan head 240 in accordance with one of the operational schemes discussed above.

Still referring to FIG. 7, the sheet feeding mechanism 250 is preferably movable relative to the enclosure 110 between a lower feed position and an upper disengaged position, to thereby facilitate movement of a scannable object into the enclosure while the scannable object is supported on the platen 130. The preferable path of movement of the sheet feeding mechanism 250 between the feed position and the disengaged position is generally indicated by the arrows marked 251.

More specifically, if a scannable object is placed upon the platen 130 when the platen is extended in the load position, then a minimum amount of clearance will be required between the sheet feeding mechanism 250 and the platen in order to move the scannable object into the enclosure while supported on the platen. That is, with a scannable object supported on the platen 130, interference between the scannable object and the sheet feeding mechanism 250 is likely when the platen is moved from t he load position to the scan position, unless the sheet feeding mechanism is raised above the platen. Such interference is especially likely in the case wherein a bulky scannable object such as a book or the like is placed on the platen 130 for scanning.

Accordingly, it is preferable that the sheet feeding mechanism 250 is movable so as to be raised to the disengaged position prior to retracting of the platen 130 to the scan position. Such movement of the sheet feeding mechanism 250 is preferably in order to decrease the likelihood of interference between the sheet feeding mechanism and a scannable object supported on the platen. As depicted in FIG. 7, the sheet feeding mechanism 250 is shown located in the lower feed position. Thus, when the sheet feeding mechanism 250 is raised to the upper disengaged position, the sheet feeding mechanism would be moved generally toward the top wall 116. In this manner, clearance is provided between the platen 130 and the sheet feeding mechanism 250.

With reference now to FIG. 8, a side view is shown in which the apparatus 200 shown in FIG. 7 is depicted. That is, the apparatus 200 depicted in FIG. 7 is shown in a side view in FIG. 8. As is seen in FIG. 8, the sheet feeding mechanism 250 is shown in the raised disengaged position, wherein clearance has been established between the platen 130 and the sheet feeding mechanism as indicated by the arrows marked 251. A study of FIG. 8 reveals that a scannable object can be placed into the enclosure 110 for scanning while supported on the platen 130 without interference between the scannable object and the sheet feeding mechanism 250.

As is also revealed from an examination of FIG. 8, the apparatus 200 can include a selectively activatable actuator mechanism 255 that is operatively connected to the sheet feeding mechanism 250, wherein selective activation of the actuator mechanism will cause the sheet feeding mechanism to be moved between the lower feed position and the upper disengaged position. In other words, the actuator mechanism 255 is preferably configured to selectively move the sheet feeding mechanism 250 away from the platen 130 to the disengaged position when scannable objects are moved into the enclosure for scanning by placement thereof on the platen when the platen is in the load position.

The actuator mechanism 255 is also preferably configured to selectively move the sheet feeding mechanism 250 toward the platen 130 to place the sheet feeding mechanism 250 into the feed position for operation thereof in an automatic sheet feeding mode as described above. The actuator mechanism 255 is preferably configured to be selectively activated or controlled by a user via a control switch and associated control systems (not shown), for example. Control means, as mentioned above, are known and thus are not discussed further herein or depicted in the accompanying figures.

Turning now to FIG. 9, a schematic diagram is shown in which a side schematic view of an image-processing apparatus 300 in accordance with yet another embodiment of the present invention is depicted. FIG. 9 is intended to illustrate the relative operative elevational locations of the various components of the apparatus 300. That is, the apparatus 300 can be generally configured in the manner of the apparatus 100 and/or 200 which are discussed above with respect to FIGS. 1 through 8.

More specifically, the apparatus 300 includes a chassis 311 that functions as a structural support for the various components of the apparatus. The apparatus 300 also includes an enclosure 110 that has been described above with respect to previously discussed embodiments. The enclosure 110 is supported on the chassis 311. An opening 136 is defined in the front wall 112 of the enclosure as described above with respect to the previously discussed embodiments.

The apparatus 300 preferably includes a movable panel 338 that can be moved between a closed position and an open position. The panel can be supported on the enclosure 110 as shown. When the panel 338 is in the closed position, the opening 136 is preferably substantially closed, while when the panel is in the open position, the platen 130 can move through the opening along with a scannable object (not shown) that can be supported on the platen. That is, as described above with respect to the previously discussed embodiments, the platen 130 is configured to pass through the opening 136 when moving between the retracted scan position and the extended load position.

As is further seen from an examination of FIG. 9, a guide device 134 can be included in the apparatus 300. The guide device can be operatively supported on the chassis 311 and within the enclosure 110. The guide device 134 is preferably configured to operatively contact the platen 130 for movably guiding the platen as the platen moves between the scan position and the load position.

The apparatus 300 can also include a selectively activatable actuator member 260 that is operatively linked to the platen 130 for at least partially moving the platen between the scan position and the load position. Preferably, the actuator member 260 is located within the enclosure 110 and is at least partially supported on the chassis 311. As described above, the actuator member 260 can be a passive type of actuator member such as a spring or the like. Alternatively, the actuator member 260 can be an active actuator member such as a selectively controlled motive device such as an electric motor or the like.

As is further seen, the apparatus 300 can include a scan head that is operatively supported on the chassis 311 and within the enclosure 110. As shown, the scan head is preferably operatively located such that the platen 130, when in the scan position, is above the scan head and in juxtaposed operative relation thereto. That is, preferably, when the apparatus 300 has been set up for operation, the scan head 240 is operatively located below the platen 130 and in juxtaposed orientation relative thereto when the platen is in the scan position.

The apparatus 300 can further include a sheet feeding mechanism 250 that is operatively supported on the chassis 311. Preferably, the sheet feeding mechanism 250 is also operatively located within the enclosure 110 and above the platen 130 when the platen is in the scan position. A selectively activatable actuator mechanism 255 can also be included in the apparatus 300. The actuator mechanism 255 is operatively linked to the sheet feeding mechanism 250 for moving the sheet feeding mechanism between a lower feed position and an upper disengaged position. Preferably, the actuator mechanism 255 is located within the enclosure 110 and is also preferably operatively supported on the chassis 311.

An imaging device 302 can also be included in the apparatus 300. The imaging device 302 is preferably supported on the chassis 311 and within the enclosure 110. The imaging device 302 is also located above the platen 130 when the platen is located in the scan position. The imaging device 302 is configured to produce visual images on imaging media (not shown). The imaging device 302 can be configured in any of a number of known manners. The imaging device 302 is preferably communicatively connected with the scan head 240 whereby images scanned by the scan head are printable by the imaging device. That is, the imaging device 240 is preferably configured to reproduce images which are scanned by the scan head 240.

Returning now to FIG. 1, it is understood that the following illustrative discussion refers to various items that are not shown in FIG. 1, but which have already been described in the above discussion with respect to various accompanying figures as noted. In a typical operational sequence of the apparatus 100, a user can scan a scannable object by first causing the platen 130 to move from a scan position in which the platen is located within the enclosure 110, to the extended load position in which the platen is located substantially outside the enclosure as depicted.

The extension of the platen 130 from the scan position to the load position can be accomplished in any of a number of manners, depending upon the specific configuration of the apparatus 100. For example, as described above, the apparatus 100 can be configured so that the platen 130 is manually movable. In that case, the user, after moving the panel 138 to its open position, can grasp the platen 130 and move the platen outward from the enclosure to the load position.

Once the platen 130 has been placed in the load position, a scannable object can be placed upon the platen so as to be supported thereon. Then, the platen 130 can be manually moved by the user from the load position to the scan position. Such movement of the platen 130 can be accomplished by way of the user again grasping the platen and moving the platen inward relative to the enclosure 110 with the scannable object supported on the platen.

When the platen 130 is in the scan position, the platen and the scan head (not shown) are preferably in operative juxtaposed orientation relative to one another. That is, when the platen 130 is in the scan position it is located and oriented relative to the scan head such that the scan head, by way of operation thereof, can scan the scannable object supported upon the platen.

Once the platen and the scannable object have been moved into the enclosure to the scan position, the panel 138 can be moved to its closed position by the user. When the panel 138 has been closed, the user can then activate the scan head (not shown) so as to scan the scannable object as the scannable object is supported on the platen 130 and while the platen is in the scan position.

In the case wherein the apparatus 100 includes an imaging portion 102, then the imaging portion can be caused to produce a duplicate image from the scan data generated by the scan head in scanning the scannable object. The image generated by the imaging portion 102 can be produced and then deposited in the output tray 124 to await retrieval by the user.

When the scanning operation has been completed, the user can retrieve the scannable object from its supported position on the platen 130 and inside the enclosure 110 by again causing the platen to move from the scan position to the load position wherein the platen is extended from the enclosure as depicted. Once the platen 130 has been moved into the load position, the scannable object can be retrieved from the platen by the user, and the platen can be returned to the scan position inside the enclosure 110. When the platen 130 has been returned to the scan position, the panel 138 can again be placed in its closed position wherein the opening 136 is substantially closed or blocked.

With the platen 130 in the scan position and with the panel 138 in its closed position, the apparatus 100 can be caused to automatically scan a plurality of image-bearing sheets in the case wherein the apparatus includes a sheet feeding mechanism (not shown) which has been described above. That is, a stack of image-bearing sheets can be initially loaded onto the feed input tray 126.

The user can then activate the sheet feeding mechanism; wherein the sheet feeding mechanism successively picks each image-bearing sheet from the stack supported on the feed input tray 126 and moves the each sheet successively through the apparatus 100 for scanning. Once scanned, each image-bearing sheet is restacked on the feed output tray 128 for retrieval by the user.

As a further example of the operation of the apparatus 100, the platen can be alternatively configured as described above so as to be automatically movable between the scan position and the load position. That is, the apparatus 100 can alternatively include an actuator member (not shown) that is operatively connected to the platen 130 as described above with respect to the apparatus 200.

In that case, a control system (not shown) including a control switch (not shown) is preferably included in the apparatus 100, wherein the user manipulates the control switch to activate the actuator member so as to control the position of the platen 130 relative to the enclosure 110. That is, the user can cause the platen to move between the scan position and the load position by way of manipulation of a control switch.

In accordance with yet another alternative configuration, the actuator member can be substantially in the form of a passively operated resilient member such as a spring or the like, as has already been described in greater detail above. Such a passively operated actuator member can serve to at least partially move the platen 130 from the scan position to the load position. In either case, a scannable object can be placed upon, and retrieved from, the platen 130 for scanning by causing the platen to selectively move between the scan position and the load position as described above.

While the above invention has been described in language more or less specific as to structural and methodical features, it is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

What is claimed is:

1. An image processing apparatus, comprising:
an imaging portion; and
a scanning portion operatively located below the imaging portion.

2. The apparatus of claim 1, and wherein the scanning portion comprises an extensible platen that is located below the imaging portion.

3. The apparatus of claim 2, and wherein the platen is extensible between a retracted scan position and an extended load position to thereby facilitate the placement of a scannable object on the platen.

4. The apparatus of claim 1, and wherein:
both the imaging portion and the scanning portion are discrete modular units which are operatively connectable with one another; and
the imaging portion is supportable on and above the scanning portion.

5. An image processing apparatus, comprising:
an enclosure;
a scan head operatively mounted within the enclosure; and
a platen that is extensible relative to the enclosure, wherein the platen is extensible from a scan position to a load position.

6. The apparatus of claim 5, and wherein:
when the platen is in the scan position, the platen is located wholly within the enclosure; and
when the platen is in the load position, the platen protrudes substantially outside of the enclosure.

7. The apparatus of claim 6, and wherein:
the platen is slidably extensible along a substantially horizontal extension path; and
the platen is substantially horizontally oriented when in the scan position and when in the load position.

8. The apparatus of claim 7, and wherein:
the scan head is operatively movable along a scan path; and
the extension path is substantially perpendicular to the scan path.

9. The apparatus of claim 7, and wherein the apparatus is configured to scan sheets of image-bearing media, the apparatus further comprising:
a sheet feeding mechanism operatively located within the enclosure; and
a sheet path defined by the sheet feeding mechanism, wherein sheets of image-bearing media are movable along the sheet path to thereby pass through the enclosure and across the platen when the platen is in the scan position, and wherein the sheet path is substantially transverse with respect to the extension path.

10. The apparatus of claim 5, and further comprising a selectively activatable actuator member that is operatively connected to the platen, wherein selective activation of the actuator member will cause the platen to move between the scan position and the load position.

11. The apparatus of claim 9, and wherein the sheet feeding mechanism is movable relative to the enclosure between a lower feed position and an upper disengaged position, to thereby facilitate movement of a scannable object into the enclosure while supported on the platen.

12. The apparatus of claim 11, and further comprising a selectively activatable actuator mechanism that is operatively connected to the sheet feeding mechanism, and wherein selective activation of the actuator mechanism will cause the sheet feeding mechanism to be moved thereby between the feed position and the disengaged position.

13. The apparatus of claim 5, and further comprising an imaging portion operatively supported above the scan head.

14. An image processing apparatus, comprising:
a chassis;
an enclosure supported on the chassis;
a scan head operatively supported on the chassis and within the enclosure; and
a substantially flat and rigid platen that is movably supported on the chassis, wherein the platen is selectively movable between a retracted scan position and an extended load position, and wherein when the platen is in the scan position the platen is located above the scan head and in juxtaposed operative relation thereto and substantially within the enclosure, and wherein when the platen is in the load position the platen is located substantially outside of the enclosure to thereby facilitate placement of a scannable object on the platen.

15. The apparatus of claim 14, and further comprising a guide device supported on the chassis, and wherein the platen is movably supported by the guide device to thereby facilitate movement of the platen between the scan position and the load position.

16. The apparatus of claim 15, and further comprising a substantially vertical front wall defined on the enclosure, and wherein:
the front side wall defines an opening therein; and
the platen, when moving between the scan position and the load position, moves through the opening.

17. The apparatus of claim 14, and wherein the platen is slidably movable between the scan position and the load position.

18. The apparatus of claim 15, and wherein the platen is restricted by the guide device to a substantially horizontal orientation.

19. The apparatus of claim 14, and wherein the apparatus is configured to scan sheets of image-bearing media, the apparatus further comprising a sheet feeding mechanism operatively supported on the chassis and within the enclosure, wherein when the platen is in the scan position, the sheet feeding mechanism is above the platen.

20. The apparatus of claim 19, and further comprising an imaging device operatively supported on the chassis, whereby images scanned by the scan head are printable by the imaging device, and wherein the imaging device is supported above the platen when the platen is in the scan position.
